(19) United States
(12) Patent Application Publication
(10) Pub. No.: US 2013/0092221 A1
(43) Pub. Date: Apr. 18, 2013

(54) INTERMEDIATE BAND SOLAR CELL HAVING SOLUTION-PROCESSED COLLOIDAL QUANTUM DOTS AND METAL NANOPARTICLES

(71) Applicant: Universidad Politécnica De Madrid, Madrid (ES)

(72) Inventors: Manuel Joao DE MOURA DIAS MENDES, Madrid (ES); Antonio MARTÍ VEGA, Madrid (ES); Ignacio TOBÍAS GALICIA, Madrid (ES); Antonio LUQUE LÓPEZ, Madrid (ES)

(73) Assignee: UNIVERSIDAD POLITECNICA DE MADRID, Madrid (ES)

(21) Appl. No.: 13/648,757

(22) Filed: Oct. 10, 2012

Related U.S. Application Data
(60) Provisional application No. 61/547,312, filed on Oct. 14, 2011.

(51) Int. Cl. H01L 31/075; H01L 31/18

(52) U.S. Cl. 136/255; 438/87; 257/E31.061

(57) ABSTRACT

The present invention relates to a solar cell and to a method of manufacturing thereof, the solar cell comprising: a layer of an n-doped semiconductor, a layer of a p-doped semiconductor and an intermediate band layer being disposed between the n-doped and the p-doped semiconductor layers, the intermediate band layer comprising: an amorphous semiconducting host material, a plurality of colloidal quantum dots embedded in the host material and substantially uniformly distributed therein, each quantum dot comprising a core surrounded by a shell, the shell comprising a material having a higher bandgap than that of the host material, and a plurality of metal nanoparticles embedded in the host material and located at least in a plane where a plurality of quantum dots are distributed.

### CROSS REFERENCE TO RELATED APPLICATIONS

This application is filed under 35 U.S.C. §119(e) and claims priority to U.S. Provisional Patent Application No. 61/547,312, filed Oct. 14, 2011 and entitled “Intermediate Band Solar Cell Having Solution Processed Colloidal Quantum Dots and Metal Nanoparticles” in the name of Manuel Joao DE MOURA DIAS MENDEZ et al., incorporated herein by reference in its entirety.

### TECHNICAL FIELD OF THE INVENTION

The present invention relates to an intermediate band solar cell. More specifically, the present invention is directed to a solar cell which incorporates a plurality of colloidal quantum dots and metal nanoparticles embedded in a host semiconductor. The quantum dots are provided with a shell which enables the absorption of photons with energies within an extended range as compared to conventional solar cells, thus increasing the efficiency of the solar cell. The metal nanoparticles are efficient optical antennas at their surface plasmon resonance, attracting the light from their surroundings and focusing it in their near-field, thereby forming a light trapping structure in the cell that increases the absorption of light in the intermediate band and, thus, further improves the conversion efficiency of the solar cell.

The reflective element can be applied in the field of photovoltaic devices.

### BACKGROUND OF THE INVENTION

The photovoltaic (PV) material that constitutes conventional solar cells is a semiconductor whose energy bandgap determines the maximum amount of current and voltage supplied by the device. The generation of photo-current occurs when the incident photons have sufficient energy to pump electrons across the bandgap, that is, from the valence to the conduction band of the semiconductor. High bandgap values produce low currents (because fewer photons are absorbed) but high voltages, and vice versa. It has been determined by W. Shockley and H. J. Queisser (J. Appl. Phys., Vol. 32, 510 (1961), revised by Araújo and Marti, Solar Energy Materials and Solar cells, Vol. 33, N. 2, 213 (1994)) that the maximum sunlight-to-electricity conversion efficiency that can be attained by such conventional solar cells is 40.7%, having an optimal bandgap of 1.2 eV.

The above efficiency limit is applicable to most of the current commercial photovoltaic technology, since the solar cells involved are composed of a single junction with a unique bandgap. In the last decades intense research efforts have been undertaken to develop novel photovoltaic solutions in order to achieve grid parity in the final price of electricity generation. Such efforts are aimed not only at reducing the fabrication costs of the cells but also at achieving higher conversion efficiency.

One of the technological schemes proposed to surpass the Shockley-Queisser efficiency limit is the intermediate band solar cell (IBSC) (patent EP 1 130 657, A2 P9901278, U.S. Pat. No. 6,444,897). The semiconductor material that constitutes this cell is characterized by the existence of an intermediate band (IB) located between the conventional semiconductor conduction band (CB) and valence band (VB). Because of the IB, below-bandgap-energy photons can contribute to the cell photo-current by pumping electrons from the VB to the IB and from the IB to the CB. Besides, since the IB is isolated from the CB and the VB by a zero density of states, carrier relaxation between bands becomes difficult and the carrier statistics in each band is described by its own quasi-Fermi level. As such, the voltage supplied by the cell is limited by the high bandgap E_{CV} (between the VB and CB) of the host semiconductor, and not by any of the lower bandgaps: E_{IV} (between the VB and IB) or E_{CI} (between the IB and CB).

In an IBSC, the optimum semiconductor bandgaps correspond to: E_{CV}=1.95 eV, E_{CI}=0.71 eV and E_{IV}=1.24 eV. The maximum conversion efficiency that can be obtained by an IBSC having such optimal parameters is 63.2% (at maximum sunlight concentration), as compared with the Shockley-Queisser limit of 40.7% for a single-gap cell.

IBSCs are usually fabricated using nanotechnology, incorporating an array of quantum dots (QDs) in the cell semiconductor material (Marti, Cuadra and Luque, Conference Record of the Twenty-Eighth Ieee Photovoltaic Specialists Conference—2000 (Ieee, New York, pp. 940-943 (2000)). The IB is formed by the ground-state (lowest energy level) of the quantum-confined wavefunctions of the electrons in the three dimensional potential wells in the conduction band. If the confined electron wavefunctions are sufficiently delocalized (or there is a high enough QD density) they can overlap and form a “mini-band”, which allows the mobility of carriers within the IB. This is an advantageous (though not essential) condition for the IBSC, in order for the cell to be able to compensate for possible non-uniformities in the illumination or doping profiles (Marti, Cuadra and Luque, IEEE Transactions on Electron Devices, Vol. 49, pp. 1632-1639 (2002)).

Quantum dot intermediate band solar cells (QD-IBSCs) have been fabricated until now with QDs epitaxially grown on crystalline semiconductor wafers using the Stranski-Krastanov (SK) method (Luque, Marti, Stanley, Lopez, Cuadra, Zhou, Pearson and McKee, Journal of Applied Physics (AIP), Vol. 96, pp. 903-909 (2004)). Such devices have been based on III-V semiconductor materials, the most common example being the case of Indium Arsenide (InAs) QDs epitaxially grown in a Gallium Arsenide (GaAs) host. The SK technique consists in an initial growth of a thin wetting layer of InAs over the GaAs substrate. When the wetting layer reaches a critical thickness (usually a few monolayers), the strain unbalance between the InAs and GaAs lattice constant causes the coalescence of InAs “islands” that later will constitute the QDs.

Nevertheless, the impact of the intermediate band effects on the performance of these cells is still marginal since the band structure obtained is far from the optimal IB structure proposed (Luque and Marti, Phys. Rev. Lett., Vol. 78, pp. 5014-5017 (1997)). In addition, the presence of the thin wetting layer below the QDs creates an effective reduction of the host material bandgap, and disrupts the three-dimensional electronic confinement required for the QDs since it acts as an area of one-dimensional confinement (quantum well). Besides, the III-V QDs produced by the SK method have irregular and highly anisotropic shapes with in-plane dimensions considerably higher than the normal-to-plane dimension. The larger in-plane dimensions of these QDs cause the appearance of several discrete levels between the QDs ground-state and the CB that enable the thermal (non-radiative) coupling between the IB and the CB, which lowers the cell voltage.

Furthermore, another drawback of the QD-IBSCs fabricated up to now, is the low photon absorption provided by the intermediate band due to the low absorptivity of the QDs. A typical IB material, formed by an array of QDs, exhibits three absorption coefficients related to the aforementioned three electronic transitions—from the valence band to the conduction band (α_{CV}), from the valence band to the intermediate band (α_{IV}) and from the intermediate band to the conduction band (α_{CI}). The first absorption coefficient (α_{CV}) is associated to the host semiconductor and is typically on the order of magnitude of 10⁴ cm⁻¹ (the case of GaAs or amorphous silicon). The coefficient α_{IV} is usually one or two orders below (^{˜}10²⁻³ cm⁻¹), as experimentally observed in prototype IBSCs (Luque, Marti, Stanley, Lopez, Cuadra, Zhou, Pearson and McKee, Journal of Applied Physics (AIP), Vol. 96, pp. 903-909 (2004)). However, the absorption of photons from the intermediate band to the conduction band (α_{CI}) is estimated to be much lower than the previous two coefficients, since it implies a transition from a confined (localized) state within the QD to an extended (delocalized) state in the host material conduction band. The localized-to-delocalized character of the transition leads to a low wavefunction overlapping between the two states, which results in a small matrix element for such optical transition. Besides, quantum selection rules determine that such matrix element is only non-zero if the confined and extended states differ only in one quantum number (nₓ, n_{y} or n_{z} associated, respectively, to confinement along the x, y and z directions). Thus, an electron in the intermediate band can only transition to a state close to the minimum of the conduction band, so it can only absorb photons having energy higher but close to E_{CI}. As such, α_{CI} not only has a small magnitude but also has a narrow spectral width close to E_{CI}, not allowing the absorption of most of the photons with energies below E_{IV} by the IB material.

### SUMMARY OF THE INVENTION

The aforementioned drawbacks are solved by means of a solar cell according to claim 1 and a method for the manufacturing thereof. The dependent claims define preferred embodiments of the invention. The present invention solves the problems described above, by adding important modifications related to the structure and manufacturing of the QDs and to the incorporation of a plasmonic light trapping system to enhance the intermediate band absorption.

In a first aspect, the invention defines a solar cell comprising:
a layer of an n-doped semiconductor,
a layer of a p-doped semiconductor,
an intermediate band layer being disposed between the n-doped and the p-doped semiconductor layers, the intermediate band layer comprising:
   an amorphous semiconducting host material,
   a plurality of colloidal quantum dots embedded in the host material and substantially uniformly distributed therein, each quantum dot comprising a core surrounded by a shell, the shell comprising a material having a higher bandgap than that of the host material, and
   a plurality of metal nanoparticles embedded in the host material and located at least in a plane where a plurality of quantum dots are distributed.

The intermediate band layer will be understood as the region comprising the host material and the plurality of quantum dots which cause the appearance of the intermediate band. The intermediate band layer as defined can comprise a plurality of quantum dots distributed on a single plane or distributed on several stacked planes.

Advantageously, colloidal quantum dots (CQD) are synthesized in liquid solution, which allows a high degree of control over their size, shape, and composition. CQD arrays can be assembled in any substrate through inexpensive patterning processes such as spin-casting, dip-coating and inkjet printing, which offer the additional advantage of being highly scalable for the fabrication of large-area electronic devices such as entire PV modules.

It will be understood that the quantum dots being colloidal involves a number of features, among which: the quantum dots being substantially spherical and produced with highly monodispersed diameters in the range of 1-100 nanometers.

The CQDs of most interest for application in IBSCs are those that emit in the infrared (IR) range, therefore composed by semiconductor materials with low bulk bandgap. Those that exhibit the best properties are the IV-VI series of semiconductors, particularly the lead chalcogenides (PbS, PbSe and PbTe). This is not only due to their low bandgap but also due to a set of unique characteristics that these semiconductors possess:
large optical dielectric constants (e.g. 17.6 and 22.1 in the IR for PbS and PbSe, respectively, as compared to 11.9 for Si)
the effective masses of the electron (mₑ) and hole (mₕ) are small and approximately equal (e.g. mₑ=mₕ≈0.1m₀ and 0.04m₀ for PbS and PbSe, respectively, as compared to mₑ=0.26m₀ and mₕ=0.36m₀ for Si; where m₀ is the electronic mass), and the Bohr radii (a_{B}) are large (e.g. a_{B}=18 nm and 46 nm for PbS and PbSe, respectively, as compared to 4.3 nm for Si)
are naturally occurring minerals which crystallize in the highly symmetrical sodium chloride structure
have direct bandgap transitions at the L point of the Brillouin zone

Particle volume to Bohr radii ratios of 0.04 are attainable with the lead chalcogenides as opposed to 0.16 with the much-studied classical CdSe nanoparticle system (a condition that applies to all the II-VI and III-V materials, with the possible exception of InSb). The large Bohr radius of lead chalcogenides enables a wide tunability of their band structure according to the particle size. This allows the production of CQDs having effective bandgaps at any energy in the IR range with particles of a few nanometers diameter. Besides, a higher Bohr radius implies a higher delocalization of the carriers, enabling greater electronic coupling between the wavefunctions in the QDs, thus reducing the effect of the nanoparticle surface traps and therefore facilitating charge transport.

On the other hand, the solar cell of the invention also incorporates a light trapping system using metal nanoparticles (MNPs) that act as optical antennas to enhance light harvesting by the cell material. During the last decade the development of colloidal chemistry has resulted in methods capable of yielding high control over a wide range of shapes, sizes and composition of MNPs.

MNPs exhibit strong scattering resonance in the optical regime, at frequencies that can be tuned by engineering the particle shape. These resonances occur when the frequency of the electromagnetic (EM) field of the illuminating light matches the frequency of the collective oscillations of the conduction electrons in the MNP. Due to the nanoscopic size of the metal nanoparticles, its conduction electrons are strongly bound to their surface, thus the MNP geometry significantly influences the frequency at which they oscillate. Therefore, in MNPs these collective oscillations are known as surface plasmons (SPs). At the SP resonance the pronounced polarizability of the MNP effectively draws the energy supplied by an incident EM wave into the particle. This produces a scattered near-field whose intensity can be several orders of magnitude higher than that of the incident field, up to a distance of about the MNP size. Such intense field can enhance the absorption of light in the material surrounding the MNPs by a factor on the order of 10 or higher.

In a preferred embodiment, the quantum dots shell material is selected from the group consisting of oxides, nitrides, carbides and alloys thereof.

In a preferred embodiment, the quantum dots shell has a thickness in the range of 0.1-5 nanometers.

In a preferred embodiment, the quantum dots core material is selected from the group consisting of: lead chalcogenides, Si, Ge, and III-V and II-VI compound semiconductors and multinary alloys thereof.

In a preferred embodiment, the quantum dots have a diameter in the range of 1-10 nanometers.

In a preferred embodiment, the host material is selected from the group consisting of:
hydrogenated amorphous silicon, preferably alloyed with carbon,
a conjugated conductive polymer selected from the group of organic derivatives of the type poly[p-phenylene vinylene] (PPV), polythiophene (PT) or polyfluorene (PF), and
a material selected from the group of I-III-VI₂ chalcopyrite semiconductors and derivatives obtained from deviations in the stoichiometry thereof.

In a preferred embodiment, the nanoparticles embedded in the host material are colloidal nanoparticles.

In a preferred embodiment, the metal nanoparticles comprise a metal core surrounded by a shell made of an insulating material or a semiconductor having a higher bandgap than that of the host material.

In a preferred embodiment, the nanoparticles shell material is an oxide.

In a preferred embodiment, the nanoparticles shell has a thickness in the range of 1-10 nanometers.

In a preferred embodiment, the nanoparticles metal core is made of a noble metal, preferably silver or gold.

In a preferred embodiment, the metal nanoparticles have a diameter in the range of 10-100 nanometers.

In a preferred embodiment, the metal nanoparticles shape is substantially spheroidal, the nanoparticles being embedded in the host material having their spheroid symmetry axis substantially parallel to the illuminating light propagation direction.

In a preferred embodiment, the colloidal quantum dots and the nanoparticles are disposed in the host material in such a way that each quantum dot is positioned within a distance of substantially the nanoparticle size from the surface of at least one nanoparticle.

In a preferred embodiment, the intermediate band layer has a thickness in the range of 0.1-5 micrometers.

In a preferred embodiment, at least one of the n-doped and the p-doped semiconductor layers is made of a material selected from the group consisting of:
hydrogenated amorphous silicon,
a conjugated conductive polymer selected from the group of organic derivatives of the type poly[p-phenylene vinylene] (PPV), polythiophene (PT) or polyfluorene (PF), and
a material selected from the group of I-III-VI₂ chalcopyrite semiconductors and derivatives obtained from deviations in the stoichiometry thereof.

In a preferred embodiment, at least one of the n-doped and the p-doped semiconductor layers has a thickness in the range of 10-500 nanometers.

In a second aspect, the invention defines a method for manufacturing a solar cell, comprising the following stages:
a. depositing a first electrode layer on a supporting substrate;
b. depositing a first doped semiconductor layer on the first electrode substrate;
c. depositing an intermediate band layer on the first doped semiconductor layer;
d. depositing a second doped semiconductor layer on the intermediate band layer, the doping of the second doped semiconductor being opposed to the doping of the first doped semiconductor;
e. depositing a second electrode layer on the second doped semiconductor layer;
   wherein the step of depositing an intermediate band layer on the first doped semiconductor layer comprises:
c1. depositing a first layer of a host material;
c2. depositing on the host material layer colloidal metal nanoparticles to form a nanoparticle array;
c3. depositing colloidal quantum dots on the host material layer, such that in the array of quantum dots and nanoparticles, each quantum dot is positioned within a distance of substantially the nanoparticle size from the surface of at least one nanoparticle, the order of stages c2 and c3 being interchangeable, and
c4. depositing a second layer of host material to cover the array of quantum dots and nanoparticles.

In a preferred embodiment of the method, the stages c2 to c4 are performed a number of times to produce an intermediate layer with a plurality of stacked quantum dot and nanoparticles layers.

All the features described in this specification (including the claims, description and drawings) and/or all the steps of the described method can be combined in any combination, with the exception of combinations of such mutually exclusive features and/or steps.

### BRIEF DESCRIPTION OF THE DRAWINGS

To better understand the invention, its objects and advantages, the following figures are attached to the specification in which the following is depicted:

FIG. 1 shows a schematic front view of the layer structure of the solar cell of an embodiment of the present invention.

FIG. 2 shows a schematic energy band diagram of the solar cell of an embodiment of the present invention.

FIG. 3 shows a schematic energy band diagram of a colloidal quantum dot embedded in the host semiconductor material.

FIG. 4 shows a schematic plot of the absorption, as a function of photon energy, of the intermediate band material comprising an array of colloidal quantum dots enclosed in a shell and embedded in a host semiconductor.

FIG. 5 shows a top view of an array of colloidal quantum dots and metal nanoparticles deposited on a layer of host material.

FIG. 6 shows a front view of an array of colloidal quantum dots and metal nanoparticles deposited on top of a layer of host material and then covered by another layer of host material.

### EMBODIMENTS OF THE INVENTION

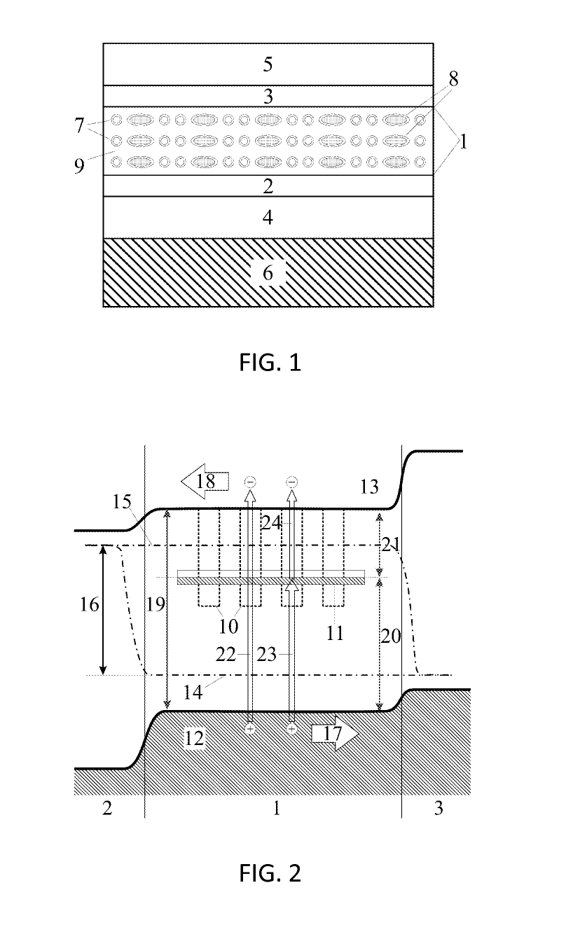

FIGS. 1 and 2 respectively show the layer structure and the energy band diagram of a solar cell according to an embodiment of the present invention. In FIG. 1 an IB layer (1) is shown sandwiched between an n-doped layer (2) and a p-doped layer (3), acting respectively as base and emitter. In a use situation of the solar cell, current is extracted from the cell through first and second (4, 5) metallic contacts. The whole cell structure is mounted on a substrate (6) that acts as a mechanical support for the layered structure.

Referring to the depicted embodiment, in FIGS. 1 and 2 the IB layer (1) comprises a plurality of colloidal quantum dots (CQDs) (7) and a plurality of colloidal metal nanoparticles (MNPs) (8) embedded in a host semiconductor (9) made of an inorganic or organic amorphous material. The ground-state confined energy levels in the potential wells (10) of the CQDs form an intermediate band (11) in between the valence band (12) and the conduction band (13) of the host semiconductor (9). The array of metal nanoparticles (8) is a light trapping structure, each MNP concentrating the incoming light in the neighboring CQDs (7), thereby increasing their absorption. The base (2) and emitter (3) doped layers are made of a semiconducting material and they anchor the hole (14) and electron (15) quasi-Fermi levels respectively, so that the output voltage of the cell is determined by the split (16) between these quasi-Fermi levels. The p-doped emitter layer (3) only allows holes (17) to pass through and the n-doped base layer (2) only allows electrons (18). Besides, the base (2) and emitter (3) layers also isolate the IB layer (1), preventing it from being short-circuited by the metallic contacts (4, 5).

In further detail, still referring to the embodiment of FIG. 1, the cell is intended to be illuminated from the top contact layer (5), so such layer is made to allow the light to pass through, e.g. it is made of a transparent conductive material or it is a metallic contact grid. The bottom contact layer (4) is in this embodiment a metallic mirror, so that the light that is not absorbed in a first pass through the cell material is reflected back into the cell by the bottom contact layer (4). As such, the bottom contact (4), apart from extracting the generated current, acts as a back reflector thus contributing to the light confinement in the cell. In this embodiment, it will be understood that the top layer is closer to the incident light than the bottom layer.

The substrate (6) may be made either of a rigid (typically glass or a low-cost wafer) or flexible (e.g. plastic or metal foil) material. The cell structure composed by the layers depicted in the figure can be mounted on top of the substrate (6), following the arrangement shown in FIG. 1, or beneath the substrate if the substrate is transparent. In the latter configuration the substrate is termed superstrate, acting as window for the illumination and as part of the cell encapsulation.

In addition to the layers represented in FIG. 1, additional layers can exist for different purposes as, for example, the inclusion of buffer layers between the doped layers (2, 3) and the contacts (4, 5) to passivate surface defects and ease the current extraction.

In a preferred embodiment, the IB layer (1) of FIGS. 1 and 2 comprises a host material (9), made of a semiconductor with a bulk bandgap (E_{CV}) close to the optimal value of E_{CV}=1.95 eV, in which an array of CQDs (7) and MNPs (8), both previously synthesized in colloidal solution, is embedded. The embedded array of CQDs (7) and MNPs (8) is constructed to extend the absorption and consequent photo-current generation of the host material (9) to energies below E_{CV}, through the creation of an intermediate band (11). Since the intermediate band is electrically isolated, the generated current is delivered to the contacts (4, 5) through the host material (9). Therefore, the host material (9) has to allow sufficiently high carrier mobility so that the energy of the photo-excited electrons and holes is not lost during transport.

The host material (9) of the IB layer (1) may be a low-cost inorganic or organic amorphous semiconductor such as those used in thin-film technology, in order to allow the inexpensive fabrication of the present device. Three types of materials are preferred for the host semiconductor material (9) of the IB layer (1): hydrogenated amorphous silicon, a multinary chalcopyrite compound, or a conjugated conductive polymer.

If the host material (9) is hydrogenated amorphous silicon (a-Si:H), it is preferably alloyed with carbon to provide the desired semiconductor bandgap of E_{CV}=1.95 eV. Increasing concentration (x) of carbon atoms widens the bandgap of amorphous alloys of hydrogenated silicon and carbon (a-Si₁₋ₓCₓ:H). This allows the tuning of the bandgap of the compound from a minimum value of 1.75 eV without carbon (x=0) to about 3 eV with a-SiC:H (x=1). Therefore, the host material made of hydrogenated amorphous silicon will preferably have an appropriate carbon concentration (x) that sets the bandgap equal to substantially E_{CV}=1.95 eV.

If the host material (9) is a multinary chalcopyrite compound, it will preferably be a derivative of the group of I-III-VI₂ semiconductors of the type (Cu,Ag)(Al,Ga,In)(S,Se,Te)₂ obtained from the deviations in the stoichiometry that provide an alloy having a bandgap close to the optimum value E_{CV}=1.95 eV. Examples of suitable multinary chalcopyrite semiconductors of the type (Cu,Ag)(Al,Ga,In)(S,Se,Te)₂ are: CuAlTe₂, In₂S₃, AgInS₂, AgGaSe₂ and CuGaSe₂ with bandgaps of 2.1, 2.0, 1.9, 1.8 and 1.7 eV, respectively.

If the host material (9) is a conjugated conductive polymer, it will preferably be an organic derivative based on PPV-(poly[p-phenylene vinylene]), PT-(polythiophene) or PF-(polyfluorene) obtained by chemical modification of the substituents and/or side groups to provide a bandgap close to E_{CV}=1.95 eV. Examples of polymeric compounds with the required conditions are: MEH-PPV (poly[2-methoxy-5-(2′-ethyl-hexyloxy)-1,4-phenylene vinylene]), PT, P3HT (poly[3-hexylthiophene]), PFR3-S (poly[9,9-d]octylfluorene-2,7-diyl-alt-2,5-bis(2-thienyl-1-cyanovinyl)-1-(2′-ethylhexyloxy)-4-methoxy-benzene-5″,5″-diyl]) and PFR4-S (poly[9,9-d]octylfluorene-2,7-diyl-alt-2,5-bis(2-thienyl-2-cyanovinyl)-1-(2′-ethylhexyloxy)-4-methoxy-benzene-5″,5″-diyl]) whose bandgaps are respectively 2.2, 2.0, 1.9, 2.21 and 1.95 eV.

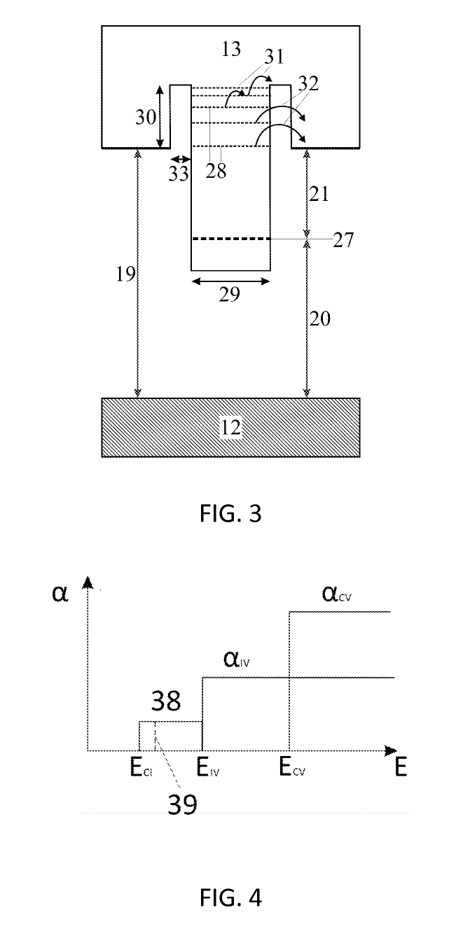

The quantum dots (7) of the cell according to the invention have a substantially spherical shape and comprise a semiconductor core (25) surrounded by a thin shell (26) made of a semiconductor or an insulating material with a wider bandgap than that of the host material (9). In more detail, referring to the CQDs core (25), FIG. 3 shows the energy band diagram of one CQD (7), embedded in the host semiconductor material (9) with a bandgap E_{CV} (19), the QD (7) having only one electronic level (the ground-state confined level) (27) below the conduction band (13) minimum. Such level forms the intermediate band (11) and is separated from the conduction band minimum by an energy gap E_{CI} (21) of substantially 0.71 eV and from the valence band by an energy gap E_{IV} (20) of substantially 1.24 eV. The second, third and subsequent confined levels (28) lie above or at the conduction band minimum. In order for such conditions to be met, two requirements have to be enforced relative to the CQDs core (25).

First, the diameter (29) of the CQDs core (25) has to be sufficiently small, since the separation between the energy of the confined levels within the dot increases as the CQD size decreases. Therefore, the CQD core diameter will preferably be in the 1-10 nanometer range to allow a separation between its first and second confined levels above or equal to E_{CI}=0.71 eV.

In addition, the material of the CQDs core (25) has to be a semiconductor having a bulk bandgap below E_{IV}=1.24 eV since the energy gap (20) between the quantum dot valence band and its first electronic state (27) increases with decreasing quantum dot diameter (increasing quantum confinement).

Referring now to the details of the CQDs shell (26), FIG. 4 shows the absorption (a) as a function of energy (E) of the IB material composed by an array of quantum dots, each having the energy band diagram of FIG. 3. The absorption spectrum of FIG. 4 comprises three absorption coefficients, α_{CV}, α_{IV} and α_{CI}, related respectively to the three aforementioned electronic transitions: from the valence band to the conduction band (22), from the valence band to the intermediate band (23) and from the intermediate band to the conduction band (24). The α_{CI} coefficient is shown comparing the case of CQDs with (38) and without shell (39). The absorption spectrum of α_{CI} in a case where the quantum dots are not provided with a shell as defined in the invention would extend from E_{CI} to the dashed line denoted by (39) in the figure. The CQD shell provides a potential barrier for the excited electrons that extends the absorption spectrum of α_{CI} (38) to energies up to the minimum energy (E_{IV}) absorbed by α_{IV}.

In further detail, still referring to the CQDs shell (26), FIG. 3 shows the energy difference (E_{B}) between the top of the potential barrier created by the CQDs shell and the minimum of the CB (13). This potential barrier extends the CQD electronic confinement to energies above the CB minimum, creating localized states (28) between the conduction band minimum and the top of the barrier walls to which electrons from the QD ground-state, the intermediate band (27), can jump. Since such transitions are from a localized state to another localized state, their associated absorption coefficient is high compared to transitions to CB extended states. Thus, this solution allows the electrons in the IB to better absorb photons with energies higher than E_{CI} (up to E_{CI}+E_{B}). The excited electrons in the localized states (28) of the barrier then transition to the host material conduction band (13) by thermal escape (31) or tunneling (32) across the shell barrier.

The quantum dots shell thickness (33) has to be small, preferably in the range of 0.1-5 nanometers to allow the tunneling (32) mechanism to occur.

The quantum dots shell is made of a material having a higher bandgap than that of the host material (9). In a preferred embodiment, the quantum dots shell material is selected from the group consisting of oxides, nitrides, carbides and alloys thereof.

The preferred shell (26) material is that which provides an optimal potential barrier height substantially equal to E_{B}=E_{IV}-E_{CI}=0.53 eV. Such barrier height enables the absorption of photons by the CQDs with energies in between E_{CI} and E_{IV}, thus extending the spectral width of α_{CI} up to that of α_{IV}, as represented in FIG. 4. In this way, the present solar cell is able to generate photo-current from a broader range of photon energies than the conventional quantum dot intermediate band solar cells, whose α_{CI} is limited to energies close to E_{CI}.

The construction details of the CQDs shell (26) of FIG. 3 are that it may be formed in solution phase, during the colloidal synthesis of the CQDs, or by controlled modification of the CQD surface after their deposition onto the host material surface. The CQD shell (26) may be made by an heterophase of high-bandgap compounds (such as oxides, nitrides or carbides) alloyed with the CQD core material. The higher the concentration of such compounds in the CQD shell material, the higher the barrier height (E_{B}) can be and, thus, the higher the maximum energy absorbed relative to transitions from the intermediate to the conduction band can be (given by E_{CI}+E_{B}). Therefore, the optimal concentration of the high-bandgap compounds in the shell material is that which provides a barrier height of substantially E_{B}=0.53 eV.

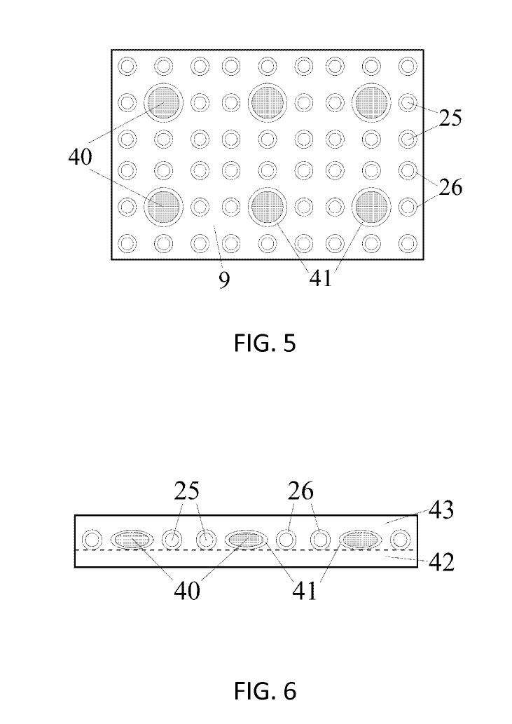

Referring now to the details of the MNPs (8) of the IB layer (1), FIGS. 5 and 6 show an array of MNPs comprising a metallic core (40) surrounded by a passivating shell (41), embedded in the host material (9) on the same layer as the CQDs (7). The MNPs are optical antennas for the incident light, bringing the incident energy from their surroundings and focusing it in their near-field where the CQDs are located. In this way, the array of MNPs constitutes a light trapping structure that can increase the amount of light absorbed by the CQDs and thereby the magnitude of the sub-bandgap IB absorption coefficients (α_{CI}, α_{IV}). The solar cell of the invention is particularly compatible with the use of such light trapping mechanism, since both the MNPs and CQDs are formed in colloidal solution.

In further detail, referring to the MNPs core (40) of FIGS. 5 and 6, its size has to be much smaller than the wavelength (λ) of the illuminating light for the MNPs to scatter in the electrostatic regime and therefore allow a maximum intensity of the produced near-field. The preferential wavelength range for absorption enhancement corresponds to that of the sub-bandgap photons absorbed by the IB, i.e. in between E_{CV}=1.95 eV (λ=0.64 micrometers) and E_{CI}=0.71 eV (λ=1.75 micrometers). Therefore, the size of the MNP core should be at least one order of magnitude below the micrometer, in the range of 10-100 nanometers.

Although the MNPs core (40) may be made of any metallic material, noble metals such as gold or silver are preferred due to the relatively low imaginary part (associated to light attenuation) and high real part of the dielectric function of these materials, in the sunlight frequency range, which allows a more pronounced surface plasmon (SP) resonance relative to other materials.

Referring now to the MNPs passivating shell (41) of FIGS. 5 and 6, it provides a potential barrier for the conducting electrons and holes, preventing them from reaching the MNP core (40). The inclusion of such barrier is important since the MNPs core (40) is made of a metallic material that can trap the free carriers and cause electron-hole recombination, which lowers the photo-current supplied by the cell. The MNPs passivating shell (41) is made of an insulating material, such as silicon dioxide, or a semiconductor having a higher bandgap than that of the host material (9), which electrically isolates the metallic material of the MNPs core (40). The thickness of the MNPs passivating shell (41) should be in the range of 1-10 nanometers, so that the MNPs shell can be sufficiently thin to avoid quenching the light scattered by the MNPs but high enough to prevent carrier tunneling across its potential barrier.

In more detail, still referring to the MNPs (8) of the IB layer (1), the shape of the MNPs has to be analytically calculated, employing the electrostatic approximation, to provide the maximum absorption enhancement in the CQDs (7). The calculation may be performed by taking an ellipsoidal shape for the MNPs defined by orthogonal semi-axes a, b and c; where c is oriented along the incident light propagation direction. Due to the unpolarized nature of sunlight, the incident electric field vector can assume any orientation orthogonal to the light propagation direction. Therefore, for the MNP to respond equally to any such polarizations, its shape has to be a spheroid with a=b. Therefore, when the MNPs are viewed from the light propagation direction they appear circular, as shown in FIG. 5.

For MNPs with no passivating shell, i.e. solely comprising the metallic core (40), the absorption enhancement in the CQDs is proportional to the square of the MNP polarizability (p) which is given by:

$$p = \frac{{ɛ}_{P} - {ɛ}_{m}}{{ɛ}_{m} + {L}_{a} ( {ɛ}_{P} - {ɛ}_{m} )} \qquad ( 1 )$$

Here ∈ₚ is the particle dielectric function (square of the refractive index) and ∈ₘ is that of the medium, both frequency-dependent. The depolarization factor (Lₐ) is a geometrical factor that only depends on the particle shape, i.e. on its spheroidal aspect ratio (c/a):

$${L}_{a} = \frac{abc}{2} {\int }_{0}^{∞} \frac{d q}{( {a}^{2} + q ) f ( q )} with$$

$$f ( q ) = {[ ( {a}^{2} + q ) ( {b}^{2} + q ) ( {c}^{2} + q ) ]}^{1 / 2}$$

The polarizability p is highest at the SP resonance frequency, corresponding to the frequency (or photon energy) that maximizes Eq. 1. Such SP resonance can be tuned with the MNP aspect ratio and therefore provide absorption enhancement at distinct energies.

The presence of the passivating shell (41) around the MNP core affects its polarizability and, thus, its SP frequency. For core-shell MNPs the polarizability (p′) becomes (Bohren and Huffman, Wiley-VCH, Weinheim (2004)):

$${p}^{′} = \frac{( {ɛ}_{2} - {ɛ}_{m} ) [ {ɛ}_{2} + ( {ɛ}_{1} - {ɛ}_{2} ) ( {L}_{a}^{( 1 )} - g {L}_{a}^{( 2 )} ) ] + g {ɛ}_{2} ( {ɛ}_{1} - {ɛ}_{2} )}{\begin{matrix}[ {ɛ}_{2} + ( {ɛ}_{1} - {ɛ}_{2} ) ( {L}_{a}^{( 1 )} - g {L}_{a}^{( 2 )} ) ] [ {ɛ}_{m} + ( {ɛ}_{2} - {ɛ}_{m} ) {L}_{a}^{( 2 )} ] + \\ g {L}_{a}^{( 2 )} {ɛ}_{2} ( {ɛ}_{1} - {ɛ}_{2} )\end{matrix}} \qquad ( 2 )$$

where ∈₁ and ∈₂ are the dielectric functions of the metal core and coating, respectively. Lₐ⁽¹⁾ and Lₐ⁽²⁾Lₐ⁽²⁾ are the corresponding depolarization factors and g=c₁a₁²/(c₂a₂²) is the fraction of the total volume occupied by the inner core

$$f = \frac{{c}_{1} {a}_{1}^{2}}{{c}_{2} {a}_{2}^{2}} .$$

The calculation of the SP frequency, at which the highest absorption enhancement occurs in the CQDs, is performed in the same way as for MNPs without passivating shell, by finding the frequency that maximizes Eq. 2 for given MNP core and shell parameters. The preferential MNPs shape is that which provides an SP resonance at a photon energy within the spectral width of the lowest absorption coefficients, α_{CI} (38) or α_{IV}, of the IB material. This allows the magnitude of such sub-bandgap absorption coefficients to be increased by one (or in special cases two) orders of magnitude, for photon energies close to the MNPs' SP resonance; thereby approaching the magnitude of the host medium coefficient, α_{CV}.

The construction details of the MNPs (8) of the IB region (1) of FIG. 1, FIG. 5 and FIG. 6 are that both the MNPs core (40) and passivating shell (41) are synthesized in colloidal solution prior to their deposition onto the host material (9).

Further construction details of the array of CQDs (7) and MNPs (8), in the embodiments shown in FIG. 1, FIG. 5 and FIG. 6, are that the MNPs (8) are positioned side-by-side with the CQDs (7), both patterned substantially on the same planes on the host material (9). Such arrangement is preferred since the highest scattered light intensity occurs in the near-field region around each MNP, in the plane orthogonal to the incident light propagation direction. The near-field region is located close to the MNP surface and extends up to a distance of about the MNP size in the host material. Therefore, each CQD (7) should be located within a distance from an MNP surface lower than the MNP size. The embedment of an array of CQDs (7) and MNPs (8) in the host semiconductor (9) may be performed by a two-step process in which the array of CQDs (7) and MNPs (8) is first deposited on top of a layer of host material, denoted as bottom spacer layer (42), followed by the deposition of another layer of host material above the array, the top spacer layer (43), which covers the deposited nanoparticles. Additional layers of CQDs (7) and MNPs (8) arrays embedded in the host semiconductor may be constructed in this way by repeating the structure of FIG. 6 as many times as desired, such as illustrated in the IB material (1) of FIG. 1. The more layers are stacked in this way the higher becomes the absorption of the IB material (1). Nevertheless, the total number of such layers is limited since the total thickness of the whole IB region (1) should not exceed the carriers' diffusion length in the host material (which is typically on the order of 0.1 micrometers in amorphous semiconductors). Otherwise, the energy of the photo-generated electrons and holes can be lost by recombination before the carriers reach the contacts.

In further detail, referring now to the base (2) and emitter (3) doped layers of FIG. 1 and FIG. 2, they are preferably made of any of the materials proposed for the host semiconductor (9) of the IB region (1): hydrogenated amorphous silicon, a multinary chalcopyrite compound, or a conjugated conductive polymer. These materials are doped in a similar fashion to any conventional semiconductor by incorporating appropriate donor (n-type) or acceptor (p-type) elements in the compound, allowing the formation of the n-doped base (2) and p-doped emitter (3) layers of the IBSC structure. Since doped layers usually have a considerably larger density of defects, in comparison with their intrinsic (not doped) counterparts, the thickness of the base and emitter layers shall be small, preferably in the range of 10-30 nanometers. This also allows the underlying processes of the photovoltaic effect (absorption of light and separation of photo-generated carriers) to mainly take place in the IB region (1).

Below is described a preferred embodiment of the method of the invention for producing a solar cell as the one shown in FIG. 1.

In a first stage, the bottom contact layer (4), in this embodiment made by aluminum, is deposited onto a glass substrate (6). The substrate only acts as a mechanical support for the IBSC structure of FIG. 1. The thickness of the bottom contact layer is in the range of 0.5-2 micrometers, and it can be deposited using commercial equipment, for example by metal evaporation. The bottom contact layer, apart from being conducting, acts as a mirror reflecting the light to the cell material on top.

The second stage comprises the deposition of the base layer (2) above the bottom contact of the previous step. The material of the base layer is in this embodiment hydrogenated amorphous silicon (a-Si:H) doped with phosphorous (n-type) at a concentration of 10¹⁷-10¹⁹ cm⁻³. The thickness of this layer is in the range of 10-30 nanometers.

The third stage is the processing of the IB layer (1) on top of the n-doped base layer of the previous step. There are several steps involved here (see FIG. 6) which are summarized as follows:

1. Deposition of a thin layer (preferably in the range of 20-50 nanometers) of host material (9), in this embodiment hydrogenated amorphous silicon alloyed with carbon (a-Si₁₋ₓCₓ:H), in which the concentration (x) of carbon is that which provides a bandgap of the compound equal to E_{CV}=1.95 eV. This constitutes the bottom spacer layer of host material (42).
2. Deposition of a MNPs array (8) by controlled assembly, for example using a colloidal wet-coating technique, on top of the previous layer of host material (9).
3. Deposition of the CQDs (7), by controlled assembly, for example using a colloidal wet-coating technique, in between the spaces of the MNPs, forming an array such as that shown in FIG. 6. All the CQDs in the array should be located inside the near-field region of an MNP. Therefore, each CQD is positioned within a distance of about the MNP size from an MNP surface.

The order of steps 2 and 3 can be inverted, thus first depositing the CQDs on the bottom spacer layer of host material (42) and the MNPs (8) in between the spaces of the CQD, such that each of the CQDs in the array is be located inside the near-field region of at least one MNP.

4. The array of patterned CQDs and MNPs is covered by a layer having the same material and substantially the same thickness as the layer of host material beneath the array deposited in step 1). This corresponds to the top spacer layer (43) of host material (9).
5. On top of this spacer layer additional layers of CQD and MNP arrays can be added. This is accomplished by repeating steps 2) to 4) as many times as the number of desired QD layers. The more layers are stacked in this way the higher becomes the absorption of the IB layer. However, the total number of layers is limited since the thickness of the whole IB layer should not considerably exceed the carriers' diffusion length in the host material. Otherwise, the energy of the photo-generated electrons and holes can be lost by recombination before the carriers reach the contacts. The carrier diffusion length in hydrogenated amorphous silicon ranges from 0.1 to 0.3 micrometers, therefore the maximum number of QD layers that can be incorporated in the IB layer in this case is of 5-10 layers.

The remaining structure consists of the deposition of the emitter layer (3) and top contact layer (5). The emitter is in this embodiment the same material as the base (a-Si:H) but doped with boron (p-type) at a concentration of 10¹⁷-10¹⁹ cm⁻³. The thickness of this layer is in the range of 10-30 nanometers. All the hydrogenated amorphous silicon layers of the base, emitter and IB host material can be deposited by plasma-enhanced chemical vapor deposition (PECVD).

The top contact is a transparent conductive layer, made of indium-tin-oxide (ITO), with a thickness of 0.5-1 micrometers. The top contact can be deposited by radio-frequency magnetron sputtering.

The CQD and MNP nanostructures incorporated in the IB layer in this embodiment are now going to be described in more detail.

The CQDs are substantially spherical nanoparticles comprising a core semiconductor material (25) enclosed in a thin shell (26). The CQDs are synthesized in colloidal solution, prior to their deposition, using standard chemical procedures. While in solution, CQDs are stabilized by organic molecular ligands attached to their surface, which prevent their agglomeration. The core material is a lead chalcogenide (either PbS or PbSe) and the diameter (29) is in the range of 1-10 nanometers, chosen to allow only one confined electronic level (27), the IB (11), inside the host material bandgap (19), with an optimal separation of E_{CI}=0.71 eV (21) below the CB (13).

The CQD shell is created by controlled oxidation of the particle surface, forming a layer of oxides (such as PbXO₄ or PbXO₃) together with PbX (where X stands for S or Se) around the PbX core. The concentration of the oxide in the shell material is that which provides a potential barrier for the electrons at energies above the CB minimum of optimal height E_{B}=E_{IV}−E_{CI}=0.53 eV (30). That is the height which allows the spectral width of α_{CI} to be extended from E_{CI} to the minimum energy absorbed by α_{IV} (i.e. E_{IV}). The shell thickness (33) is of 1-3 nanometers, which is sufficiently high to allow quantum confinement in its interior but also thin enough to enable electron tunneling across its potential walls.

The MNPs are substantially spheroidal nanoparticles comprising a metallic core (40) enclosed in a thin passivating shell (41). They are synthesized in aqueous colloidal solution, prior to their deposition, using standard chemical procedures. While in solution, MNPs are stabilized by organic molecular ligands attached to their surface, which prevent their agglomeration. The MNPs core is made of silver since that is one of the metals which exhibits the most pronounced plasmonic response at optical frequencies. Its size is in the range of 10-100 nanometers, and the aspect ratio is that which maximizes Eq. 2 at the appropriate photon energy within the spectral width of α_{CI} or α_{IV} (i.e. in between E_{CI} and E_{CV}).

The MNPs shell material is composed by silicon dioxide (silica), which acts as a potential barrier for the electrons and holes preventing carrier trapping and recombination at the MNPs surface. Its thickness is of 1-3 nanometers, which is sufficiently thick to prevent carrier tunneling but also thin enough to avoid shading the light intensity scattered by the MNPs core. Such shell is grown in solution phase during the colloidal synthesis of the MNPs.

The MNPs and CQDs are patterned on the same plane, as shown in FIGS. 5 and 6, by chemically engineering the surface of the host material before deposition. First, the surface of the bottom spacer layer (42) is functionalized with a self-assembled monolayer of appropriately conjugated molecules containing an end group that binds to the dangling bonds of the host surface and another end group that binds to the ligands attached to the colloids surface. The preferential compound to functionalize the silicon-based surface of the host material is an organic amino-silane, such as APTES (3-Aminopropyltriethoxysilane) or APTMS (3-aminopropyltrimethoxysilane). Secondly, the solution containing the MNPs is spin-casted onto the functionalized host surface and the MNPs surface ligands anchor the MNPs to the amino-silane end groups. The electrostratic repulsion between the MNPs establishes an inter-particle separation distance on the surface of about twice the MNP size. The CQD dispersion is then spin-casted onto the same surface of the bottom spacer layer and the molecular ligands on the CQDs surface anchor the CQDs to the free amino-silane end groups in the areas not covered by the MNPs. Since the CQDs are smaller than the MNPs they deposit in the space between the MNPs, with a separation distance determined by their electrostatic repulsion.

Finally, a cleaning step is performed before depositing the top spacer layer of host material (43) over the array of MNPs and CQDs. The surface is cleaned from the organic compounds, or other contaminating species employed in the chemical functionalization of the surfaces, by heating the device at 300-400° C. which evaporates the molecular compounds but does not affect the colloidal particles (nor the previously deposited layers of the IBSC structure in FIG. 1). This should be followed by chemical cleaning (degreasing) in heated (^{˜}60° C.) baths of acetone, isopropanol and methanol, to wash out the contaminants without removing the deposited colloids.

The present invention provides a number of advantages relative to conventional SK-grown QD-IBSCs, which are listed in the next lines:

1. Allows the use of inexpensive materials. A significant fraction of the overall production cost of wafer-based solar cells (such as the prototype IBSCs epitaxially grown by the SK method) is associated to the material requirements, in particular to the substrate which constitutes more than 97% of the cell volume. Unlike SK-grown QDs, CQDs do not require a lattice constant close to that of the host semiconductor since they are not formed epitaxially. So, CQDs may be integrated in a broad range of host semiconductors made of Earth-abundant materials. Three types of host materials are preferred in the present invention: hydrogenated amorphous silicon, multinary compounds of the chalcopyrite type and conjugated conductive polymers. Such host materials can be deposited by low-temperature techniques, gentle enough to preserve the integrity of the embedded QDs, which enables the fabrication of the cell structure on a wide range of low-cost substrates which can be rigid (e.g. glass, metal sheet), flexible (e.g. plastic) or roll-away types (e.g. polymer foil). Such substrates, apart from allowing the reduction in the device costs, may also provide physical flexibility and lightweight (especially important for space applications).
2. Provides ease of fabrication and large scale processing. All the colloidal nanostructures present in the solar cell of the invention are solution-processed. The shell-coated CQDs and MNPs are synthesized in solution phase, and their assembly onto the device may be performed through standard wet-coating procedures (e.g. by spin or dip coating, or ink-jet printing) which can pattern an indefinitely large area in minutes. Therefore, the costs and time of fabrication are minimal when compared with the advanced technology and high number of hours required for the epitaxial growth of conventional QD structures by the SK method. The same advantages also apply to the fabrication of the proposed host materials. Both hydrogenated amorphous silicon and multinary compounds of the chalcopyrite type can be deposited by chemical vapor deposition techniques, which enable low temperature deposition over large areas. The deposition of conjugated conductive polymers and the integration of colloidal nanoparticles in such host material is even more facilitated than in inorganic semiconductors, since organic polymers are synthesized in solution and the colloidal particles may be blended together with the polymer in solution-phase before deposition.
3. Enables a higher control on the quantum dot geometry. There is little control on the size and shape of the QDs that grow by strain unbalance with the SK method. Such dots grow in the form of pyramids with a significant dispersion in their dimensions. However, QDs synthesized in colloidal solution are formed in batches with a much higher monodispersivity in size and shape. Such solutions contain spherical particles all with practically the same diameter in the range of 1-100 nanometers. Colloidal chemistry also allows the fabrication of core-shell QD structures with controlled shell growth at the monolayer level. The shell material can grow epitaxially on the surface of the core semiconductor, with the latter acting as a seed for the heterogeneous nucleation of the former.
4. The QDs have stronger quantum confinement. Since CQDs are not limited by strain requirements such as the SK QDs, they can be made much smaller, with diameters of a few nanometers, and spherical. CQDs can thus provide strong carrier confinement in all three dimensions, while SK QDs usually only have strong confinement along the layer growth direction. This is because SK QDs have a pyramidal shape whose base dimensions (on the order of tens of nanometers) are higher than the height.
5. There is no wetting layer. In the SK process the QDs nucleate on top of a thin wetting layer of the same material as the QDs. This wetting layer acts as a quantum well which disturbs the quantum confinement potential of the dots and reduces the voltage (quasi-Fermi level separation) of the cell. No such layer exists with CQDs since they are formed in solution and may be latter deposited by wet-coating over the host material surface.
6. Structures can be analytically modeled. The above advantages also facilitate modeling and comparison with quantum theory, which is important for the optimization of the physical parameters involved in the design of IBSCs. The fact that CQDs have a well-defined spherical geometry and monodisperse diameters allows their opto-electronic response to be modeled by analytically solving the Schrödinger equation in a spherical potential box. More complex numerical approaches have to be adopted for the modeling of SK QD geometries, since it is not possible to solve Schrödinger equation analytically for the case of a pyramidal potential box.
7. There is a broader range of optimal dot/host material combinations. CQDs are processed from solution independently of the host material, which allows their integration in any type of matrix material (crystalline or amorphous). This is not possible with SK QDs since they are grown epitaxially from a crystalline substrate whose lattice constant has to be close to that of the QD material. So, in the SK method the number of possible dot/host material combinations is severely limited by epitaxial constraints. The fact that no lattice requirements are needed between CQDs and host semiconductor greatly widens the set of possible dot/host material combinations that can be implemented in the solar cell. This is a major advantage for the construction of an optimal IBSC structure having the desired energy gaps (E_{CI}=0.71 eV, E_{IV}=1.24 eV and E_{CV}=1.95 eV), since in this way there is a broader range of materials that can be employed to fulfill such optimum conditions.
8. QDs may have higher delocalization of their wave functions. Although there is no physical contact between adjacent QDs, exchange interactions can occur between them and their confined wavefunctions can overlap since they spill outside the QDs. The overlap of the wavefunctions can form a continuous mini-band, which allows carrier transport within the IB. This is advantageous for the IBSC, but not a necessary condition, since it can compensate for possible non-uniformities in the illumination or doping profiles. Besides, it also strengthens the absorption coefficients associated to below-bandgap transitions due to the delocalization of the QD ground states. The higher the QD Bohr radius relative to its physical radius the more the wavefunctions spill outside the QD volume, and therefore the more delocalized the wavefunctions become. The fact that no lattice matching is required between quantum dot and host material allows the choice of more convenient materials for the QDs with a Bohr radius several times higher than that of the III-V SK QDs. For instance, with lead chalcogenide CQDs particle volume to Bohr radii ratios on the order of 0.01 are attainable, as opposed to ratios on the order of 0.1 with practically all the III-V and II-VI materials, with the possible exception of InSb.
9. Allows QDs with higher radiative lifetimes. Some of the semiconductors incorporated into CQDs can exhibit unusually long exciton lifetimes when the CQDs surfaces are well passivated. For example, lifetimes greater than 1 microsecond are observed in lead chalcogenide CQDs at room temperature, much slower than in III-V SK QDs whose lifetimes are typically sub-nanosecond (Guyot-Sionnest, Comptes Rendus Physique, Vol. 9, pp. 777-787 (2008)). The particularly high lifetimes observed in lead chalcogenide CQDs (particularly made of PbS and PbSe) are attributed to two factors. First, the weaker exchange interaction between the electron and hole in the excited state. Second, the large dielectric mismatch with the external medium which screens out the external electromagnetic field. The present CQD-IBSC strategy allows the use of QDs with lifetimes much higher than those of QDs formed by the SK technique, which is beneficial in two ways: 1) Higher lifetimes imply lower non-radiative current loss due to recombination, such as that assisted by midgap recombination centers created by QD surface states (dangling bonds) or other impurities. 2) It allows the photofilling of the IB, facilitating the absorption of photons that cause transitions from the IB to the CB. One of the requirements for the optimal performance of the IBCS is that the IB should be half-filled with electrons to provide a reasonable rate of electron promotion from the IB to the CB. This can be accomplished either through modulation doping of the region where the QDs are located (Marti, Cuadra and Luque, Conference Record of the Twenty-Eighth Ieee Photovoltaic Specialists Conference—2000 (Ieee, New York, pp. 940-943 (2000)) or by photo-generating an electron population in the IB (photofilling) sufficient for the two-step generation process to work properly (Strandberg and Reenaas, Journal of Applied Physics (AIP), Vol. 105, pp. 124512 1-8 (2009)). An IB formed with CQDs having high carrier lifetimes, such as lead chalcogenide CQDs, may be photo-filled at moderate light concentration intensities, thus providing an absorption coefficient (and therefore final efficiency) for the intermediate transitions similar to that achieved with doped QDs. This relieves the necessity of having a half-filled IB in thermal equilibrium by QD modulation doping.
10. Provides access to the QDs surface. Unlike SK QDs, the surface of CQDs is accessible for chemical modification when they are in solution phase, or after being deposited on the host material. The surface treatment of CQDs improves the opto-electronic properties of the quantum dots and their stability over time. This can be accomplished through the growth of a shell material enclosing the CQDs or the attachment of molecular ligands that eliminate the trap states formed by the superficial dangling bonds of the QDs. The incorporation of a shell in the CQDs allows the extension of the spectral response of the QD absorption associated with electronic transitions from the IB to the CB (α_{CI}), as previously described in this specification.
11. The assembly of QD lattices is facilitated. With the SK method it is difficult to control the position where the QDs nucleate in the wetting layer; they either grow on random locations or on top of other QDs previously formed in bottom layers. Colloidal deposition processes by wet-coating provides a better control over the positioning of the colloidal particles on a surface, allowing a self-assembled array of equally spaced CQDs to be formed on a surface with a remarkable degree of order. Such self-organization reduces the engineering requirements of high-cost technological equipment, such as that used in the epitaxial SK growth. Besides, other types of colloidal deposition procedures can be employed that are able to precisely engineer the deposition pattern and inter-particle spacing as required.
12. Enables the assembly of QDs with other colloidal species, such as MNPs for light trapping. The present method facilitates the integration of CQDs with any other type of colloidal particles required to improve the properties of the IB material. The proposed use of metal nanoparticles to trap light is particularly suited for implementation in the CQD-IBSC device presented here, because the MNPs are fabricated in colloidal solution, such as the CQDs, and may be assembled together with the CQDs by wet-coating colloidal deposition techniques. Nonetheless, besides MNPs, any other type of colloidal specie can be incorporated in the CQD array using controlled wet-coating assembling procedures.

As mentioned previously, colloidal deposition methods (e.g. spin-casting, dip-coating or ink-jet printing), apart from being low time consuming and inexpensive procedures, allow the scalability of the technology since they are able to pattern indefinitely large-area devices such as entire PV modules.

Besides the previously listed advantages of the present CQD-IBSC design relative to conventional SK-grown QD-IBSCs, the device detailed in this patent also presents relevant advantages relative to current single-gap solar cells with an absorbing material made of a tridimensional closed-packed array of CQDs (Emin, Singh, Han, Satoh and Islam, Solar Energy, Vol. 85, pp. 1264-1282 (2011)). In such cells the CQDs are tightly packed, spaced by organic capping ligands that passivate their surface dangling bonds but constitute potential barriers for the carrier transport. Therefore, in these devices, carriers are delivered to/from the electrodes by an inefficient hopping transport mechanism, through percolated networks across the CQDs and the capping ligands. This yields low carrier mobilities (10⁴-10⁻³ cm²/Vs are typical) and, consequently, poor cell conversion efficiency (^{˜}5%). In the IBSC of the invention, the volume between the CQDs is filled with a host semiconductor which constitutes a straightforward way to eliminate the mobility problems of these cells. In the solar cell according to the present invention, hopping transport is avoided due to the two-photon process in which a first photon is absorbed, promoting an electron from the host VB to the IB formed by the CQDs, followed by a second photon which promotes the electron from the IB to the host CB that conducts it to the contact. As such, the delivery of photo-excited carriers to/from the contacts is not performed by hopping across the CQDs but rather by typical conduction through a semiconductor material embedding the CQDs. In conventional semiconductors mobilities are several orders of magnitude higher than those of percolated CQD networks (around 10 and 10² cm²/Vs respectively for amorphous and crystalline silicon). Therefore, the incorporation of the CQDs in a semiconductor host with well-established growth techniques, as proposed in this patent, allows efficient injection and collection of charge carriers from the CQDs, with the added benefit of isolating the CQDs from the external environment which prevents their oxidation and greatly improves the device stability.

1. A solar cell comprising:
a layer of an n-doped semiconductor,
a layer of a p-doped semiconductor,
an intermediate band layer being disposed between the n-doped and the p-doped semiconductor layers, the intermediate band layer comprising:
an amorphous semiconducting host material,
a plurality of colloidal quantum dots embedded in the host material and substantially uniformly distributed therein, each quantum dot comprising a core surrounded by a shell, the shell comprising a material having a higher bandgap than that of the host material, and
a plurality of metal nanoparticles embedded in the host material and located at least in a plane where a plurality of quantum dots are distributed.

2. The solar cell according to claim 1, wherein the quantum dots shell material is selected from the group consisting of oxides, nitrides, carbides, and alloys thereof.

3. The solar cell according to claim 1, wherein the quantum dots shell has a thickness in the range of 0.1-5 nanometers.

4. The solar cell according to claim 1, wherein the quantum dots core material is selected from the group consisting of:
lead chalcogenides, and
Si, Ge, III-V and II-VI compound semiconductors and multinary alloys thereof.

5. The solar cell according to claim 1, wherein the quantum dots have a diameter in the range of 1-10 nanometers.

6. The solar cell according to claim 1, wherein the host material is selected from the group consisting of:
hydrogenated amorphous silicon, preferably alloyed with carbon,
a conjugated conductive polymer selected from the group of organic derivatives of the type poly[p-phenylene vinylene] (PPV), polythiophene (PT) or polyfluorene (PF), and
a material selected from the group of I-III-VI₂ chalcopyrite semiconductors and derivatives obtained from deviations in the stoichiometry thereof.

7. The solar cell according to claim 1, wherein the nanoparticles embedded in the host material are colloidal nanoparticles.

8. The solar cell according to claim 1, wherein the metal nanoparticles comprise a metal core surrounded by a shell made of an insulating material or a semiconductor having a higher bandgap than that of the host material.

9. The solar cell according to claim 8, wherein the nanoparticles shell material is an oxide.

10. The solar cell according to claim 8, wherein the nanoparticles shell has a thickness in the range of 1-10 nanometers.

11. The solar cell according to claim 8, wherein the nanoparticles metal core is made of a noble metal.

12. The solar cell according to claim 1, wherein the metal nanoparticles have a diameter in the range of 10-100 nanometers.

13. The solar cell according to claim 1, wherein the metal nanoparticles shape is substantially spheroidal, the nanoparticles being embedded in the host material having their spheroid symmetry axis substantially parallel to the illuminating light propagation direction.

14. The solar cell according to claim 1, wherein the colloidal quantum dots and the nanoparticles are disposed in the host material in such a way that each quantum dot is positioned within a distance of substantially the nanoparticle size from the surface of at least one nanoparticle.

15. The solar cell according to claim 1, wherein the intermediate band layer has a thickness in the range of 0.1-5 micrometers.

16. The solar cell according to claim 1, wherein at least one of the n-doped and the p-doped semiconductor layers is made of a material selected from the group consisting of:
hydrogenated amorphous silicon;
a conjugated conductive polymer selected from the group of organic derivatives of the type poly[p-phenylene vinylene] (PPV), polythiophene (PT), and polyfluorene (PF); and
a material selected from the group of I-III-VI₂ chalcopyrite semiconductors and derivatives obtained from deviations in the stoichiometry thereof.

17. The solar cell according to claim 1, wherein at least one of the n-doped and the p-doped semiconductor layers has a thickness in the range of 10-500 nanometers.

18. A method for manufacturing a solar cell, comprising the following stages:
a. depositing a first electrode layer on a supporting substrate;
b. depositing a first doped semiconductor layer on the first electrode substrate;
c. depositing an intermediate band layer on the first doped semiconductor layer;
d. depositing a second doped semiconductor layer on the intermediate band layer, the doping of the second doped semiconductor being opposed to the doping of the first doped semiconductor;
e. depositing a second electrode layer on the second doped semiconductor layer;
wherein the step of depositing an intermediate band layer on the first doped semiconductor layer comprises:
c1. depositing a first layer of a host material;
c2. depositing on the host material layer colloidal metal nanoparticles to form a nanoparticle array;
c3. depositing colloidal quantum dots on the host material layer,
such that in the array of quantum dots and nanoparticles, each quantum dot is positioned within a distance of substantially the nanoparticle size from the surface of at least one nanoparticle, the order of stages c2 and c3 being interchangeable, and
c4. depositing a second layer of host material to cover the array of quantum dots and nanoparticles.

19. The method for manufacturing a band solar cell according to claim 18, wherein the stages c2 to c4 are performed a number of times to produce an intermediate layer with a plurality of stacked quantum dot and nanoparticles layers.
